(19) United States
(12) Patent Application Publication
(10) Pub. No.: US 2012/0046892 A1
(43) Pub. Date: Feb. 23, 2012

(54) DETERMINATION OF THE INTERNAL RESISTANCE OF A BATTERY CELL OF A TRACTION BATTERY WHILE USING INDUCTIVE CELL BALANCING

(76) Inventor: Holger Fink, Stuttgart (DE)

(21) Appl. No.: 13/264,930

(22) PCT Filed: Feb. 25, 2010
(86) PCT No.: PCT/EP2010/052399

§ 371 Date: Oct. 17, 2011

(30) Foreign Application Priority Data
Apr. 17, 2009 (DE) 10 2009 002 468.9

(51) Int. Cl. G01R 31/36; G06F 19/00

(52) U.S. Cl. 702/63

(57) ABSTRACT

The invention relates to a method and a device for determining the internal resistance of a battery cell of a battery, in particular a traction battery, in which an inductive cell balancing for balancing the charging states of the battery cells is carried out, whereby the charge removed from or supplied to a battery cell is determined by a determination of the current flowing during the removal or supply of the charge. According to the invention, a first control module is provided for determining a first voltage applied to the battery cell and a first current flowing from or to the battery cell at a first time during removal or supply of the charge and for determining a second voltage applied to the battery cell and a second current flowing from or to the battery cell at a second time during removal or supply of the charge. Further provided is a calculating unit for calculating the internal resistance of the battery cell on the basis of the quotients of the difference of the second voltage and the first voltage and the difference of the second current and the first current.

### PRIOR ART

The present invention relates to a method and an apparatus for determining the internal resistance of a battery cell of a battery, in particular a traction battery, as generically defined by the preambles to claims 1 and 6.

It is remarkable that in future, both in stationary applications such as wind farms and in vehicles such as hybrid and electric vehicles, new battery systems will increasingly come into use. In the present specification, the terms battery and battery system are used, in accordance with conventional linguistic usage, for the terms accumulator and accumulator system, respectively.

The basic functional construction of a battery system in the prior art is shown in FIG. 4. To achieve the requisite power and energy data with the battery system, in a battery cell 1m individual battery cells 1a are connected in series and sometimes in parallel as well. For a series circuit of battery cells, the basic circuit diagram of a so-called traction battery for hybrid or electric vehicles is shown in FIG. 5. Between the battery cells 1a and the poles of the battery system is a so-called safety and fuse unit 16, which for instance takes on the task of connecting and disconnecting the battery 1 to and from external systems and protecting the battery system against impermissibly high currents and voltages and also provides safety functions, such as the unipolar disconnection of the battery cells 1a from the battery system poles when the battery housing is opened. A further function unit is formed by the battery management 17, which in addition to the battery state detection 17a also performs communication with other systems as well as the thermal management of the battery 1.

The function unit called battery state detection 17a shown in FIG. 4 has the task of determining the actual state of the battery 1 as well as predicting the future behavior of the battery 1, such as predicting its service life and/or predicting its range. Predicting future behavior is also called prediction. The basic structure of a model-based battery state detection is shown in FIG. 6. The model-based battery state detection and battery state prediction shown is based on an evaluation of the electrical variables of battery current and voltage as well as the temperature of the battery 1 by means of an observer 17b and a battery model 17c in a known manner. The battery state detection can be done for individual cells 1a of a battery 1; in that case, this is done on the basis of the corresponding cell voltage, cell current, and cell temperature. The battery state detection can also be done for the entire battery 1. This is then done—depending on the requisite precision—either by evaluating the states of the individual cells 1a of the battery and an aggregation, based on that, for the entire battery 1, or directly by evaluating the total battery voltage, the battery current, and the battery temperature. A common feature of all the methods in the prior art is that the courses of current, voltage and temperature that occur in normal operation of the battery 1 are used both for determining the battery state and for predicting the future behavior.

In FIG. 7, the functional principle of an arrangement for so-called resistive cell balancing of battery cells 1a is shown. The task of cell balancing is, in a series circuit of a plurality of individual cells 1a, to ensure that the cells 1a all have the same state of charge and the same cell voltage. Because of the intrinsic asymmetries among the battery cells 1a, such as slightly different capacitance and slightly different self-discharging, this could not be done without additional provisions while the battery is in operation. In resistive cell balancing, the battery cells 1a can be discharged by switching on an ohmic resistor 2 disposed parallel to the cell. In FIG. 6, the resistor 2 is switched on with the value R_{Bal}_{_{—}}ₙ via the transistor 10 (T_{Bal}_{_{—}}ₙ) parallel to the cell 1a having the number n. By discharging those cells 1a that have a higher state of charge and a higher voltage than the cells 1a with numbers n with the least state of charge and the least voltage, the states of charge or voltages can be made symmetrical over all the cells 1a of the battery 1. The voltage applied to a cell 1a is supplied, for evaluation, via a filter comprising two resistors 11, 12 and a capacitor 13 and via an A/D converter 14, to a control and evaluation unit 15, of which there is one for each cell 1a, and which communicates with a higher-order central control unit, such as the battery status detector 17a. In lithium-ion batteries, which comprise a series circuit of a plurality of individual cells 1a, the use of resistive cell balancing is state of the art. Still other methods for cell balancing exist that can in principle function without loss, such as so-called inductive cell balancing.

In FIG. 8, the fundamental principle of so-called inductive cell balancing is shown. Here all the cells 1a are connected to a circuit for cell voltage detection and for control of the inductive cell balancing, which circuit has an inductive resistor 2 as an energy storing means. The term inductive cell balancing is used when the circuit concept for adapting the cell voltages or the state of charge of the cells is based on an inductive buffer storage of the electrical energy transported in the process. The buffer storage can—depending on the circuit concept—be done in chokes or repeaters.

In inductive cell balancing, in a first step, energy is drawn from one or more cells and buffer-stored in the inductive resistor 2. In a second step, the buffer-stored energy is re-stored into one or more battery cells 1a. As examples, the following can be named:
drawing energy from one cell and re-storing it in one or more cells, in which re-storing is not done into the cell from which the energy was drawn;
drawing energy from one cell and re-storing it in one or more cells, with some of the energy being re-stored in the cell from which energy from drawn;
drawing energy from a plurality of cells and re-storing it in one or more cells, without re-storing it into those cells from which energy was drawn;
drawing energy from a plurality of cells and re-storing it in one or more cells, with some of the energy being re-stored into those cells from which energy was drawn.

In FIG. 9, as an example a circuit principle for inductive cell balancing is shown, in which chokes are used for buffer-storing energy. If the battery cell 1a (n) is discharged, for instance because it has a higher state of charge than other cells of the battery system, then by the switching on of the transistor 10 (T_{Bal}_{_{—}}ₙ), a current is built up via the chokes 2a (Lₙ_{_{—}}ᵤₚₚₑᵣ) and 2b (Lₙ_{_{—}}_{lower}), by which current the cell 1a (n) is discharged. After the shutoff of the transistor 10 (T_{Bal}_{_{—}}ₙ), the current is switched through the choke 2a (Lₙ_{_{—}}ᵤₚₚₑᵣ) into a current path via the diode 2c (Dₙ₊₁_{_{—}}₁) and charges the battery cell 1a (n+1), and the current through the choke (Lₙ_{_{—}}ᵤₚₚₑᵣ) is switched into a current path via the diode 2d (Dₙ₋₁_{_{—}}₁) and charges the battery cell 1a (n−1). In this way, with the arrangement shown in FIG. 9, energy can be drawn from one cell 1a (n) and transported into the two adjacent cells 1a (n+1, n−1), in order to perform the cell balancing.

In FIG. 9, for the sake of clarity, the detection of the cell voltages is not shown. Such detection is necessary in lithium-ion batteries both for determining the state of charge and for performing the cell balancing as well as for monitoring the adherence to the upper and lower voltage limit values of the cells. Thus the information on the individual cell voltages is available to the system.

It is the object of the present invention to present a novel concept for determining the internal resistance of the individual cells of a battery system, with which the battery state detection and prediction, compared to the present state of the art, can be achieved more robustly and precisely, and independently of the operating state of the battery.

### DISCLOSURE OF THE INVENTION

The method of the invention having the characteristics of claim 1 and the apparatus of the invention having the characteristics of claim 6 have the advantage over the prior art that they can be used for determining the internal resistance of battery cells in battery systems with inductive cell balancing, with no or only slight additional electronic circuitry expense. This method and apparatus have the advantage over the present prior art that for determining the internal resistance, again and again the same course of operation can be brought about, and as a result, especially robust, precise determination becomes possible. Moreover, the novel method and the novel apparatus have the advantage that they can be used even in phases of operation in which the battery is not outputting or drawing any power at its poles, and/or in which the battery, including the battery cell, is being charged, or in other words for instance when a vehicle is parked. This is not possible in the methods known at present, for instance with the vehicle parked. In the last instance, in which use takes place during charging of the battery, a superposition of the balancing current on the charging current takes place, which according to the invention is preferably taken into account. Determining the internal resistance in the phases of operation mentioned above is impossible in the methods known so far.

The dependent claims show preferred refinements of the invention.

Especially preferably, the method and the apparatus of the invention include the feature that the first time is selected such that the first current is equal to zero, and the second time is an arbitrary time during the ensuing discharging phase or charging phase of the battery cell.

Alternatively, the method and the apparatus of the invention espe4cially preferably include the fact that the first time is an arbitrary time during the discharging phase of the battery cell, and the second time is an arbitrary time during the same discharging phase of the battery cell.

Alternatively or in addition, the method of the invention includes the step of determining an aging-dependent increase in the internal resistance of the battery cell on the basis of a known dependency of the internal resistance on a cell temperature existing during the determination of the internal resistance and a state of charge of the battery cell existing during the determination of the internal resistance. The corresponding preferred refinement of the apparatus of the invention for this purpose includes a table, which stores in memory a dependency of the internal resistance on a cell temperature existing during the determination of the internal resistance and on a state of charge of the battery cell existing during the determination of the internal resistance, and a first evaluation unit, which determines an aging-dependent increase in the internal resistance of the battery cell on the basis of the determined internal resistance and of consulting the table.

The method according to the invention moreover alternatively or in addition includes the step of determining a frequency dependency of the internal resistance of the battery cell by means of a variation of a frequency of an excitation of the resistive cell balancing during a plurality of successive determinations of the internal resistance and/or by means of a variation of a pulse-duty factor of an excitation of the resistive cell balancing during a plurality of successive determinations of the internal resistance. The corresponding preferred refinement of the apparatus of the invention for this purpose includes a second control module for varying a frequency of an excitation of the resistive cell balancing during a plurality of successive determinations of the internal resistance and/or for varying a pulse-duty factor of an excitation of the resistive cell balancing during a plurality of successive determinations of the internal resistance, and a second evaluation unit for determining a frequency dependency of the internal resistance of the battery cell by means of evaluating the plurality of successive determinations of the internal resistance. In this preferred embodiment, the internal resistance is also determined by the novel method, as a function of the frequency of the excitation.

### DRAWINGS

One exemplary embodiment of the invention will be described in detail below in conjunction with the accompanying drawings. In the drawings:

FIG. 1 is a basic circuit diagram of a first preferred embodiment of an apparatus according to the invention for determining the internal resistance of a battery cell;

FIG. 2 shows a first example for the excitation of the battery cells, for determining the frequency dependency of the internal resistance by way of varying the excitation frequency;

FIG. 3 shows a second example for the excitation of the battery cells, for determining the frequency dependency of the internal resistance by way of varying the pulse-duty factor;

FIG. 4 shows a functional construction of a battery system in accordance with the prior art;

FIG. 5 is a further basic circuit diagram of a battery system in accordance with the present prior art;

FIG. 6 is a basic circuit diagram of model-based battery state detection and prediction in accordance with the prior art;

FIG. 7 shows a basic circuit diagram of an arrangement for resistive cell balancing in accordance with the prior art;

FIG. 8 shows a basic circuit diagram of an arrangement for inductive cell balancing of the battery cells in accordance with the prior art; and

FIG. 9 shows an example of a circuit for implementing inductive cell balancing of the battery cells in accordance with the prior art.

### PREFERRED EMBODIMENTS OF THE INVENTION

Preferred embodiments of the invention will be described below in detail, in conjunction with the drawings.

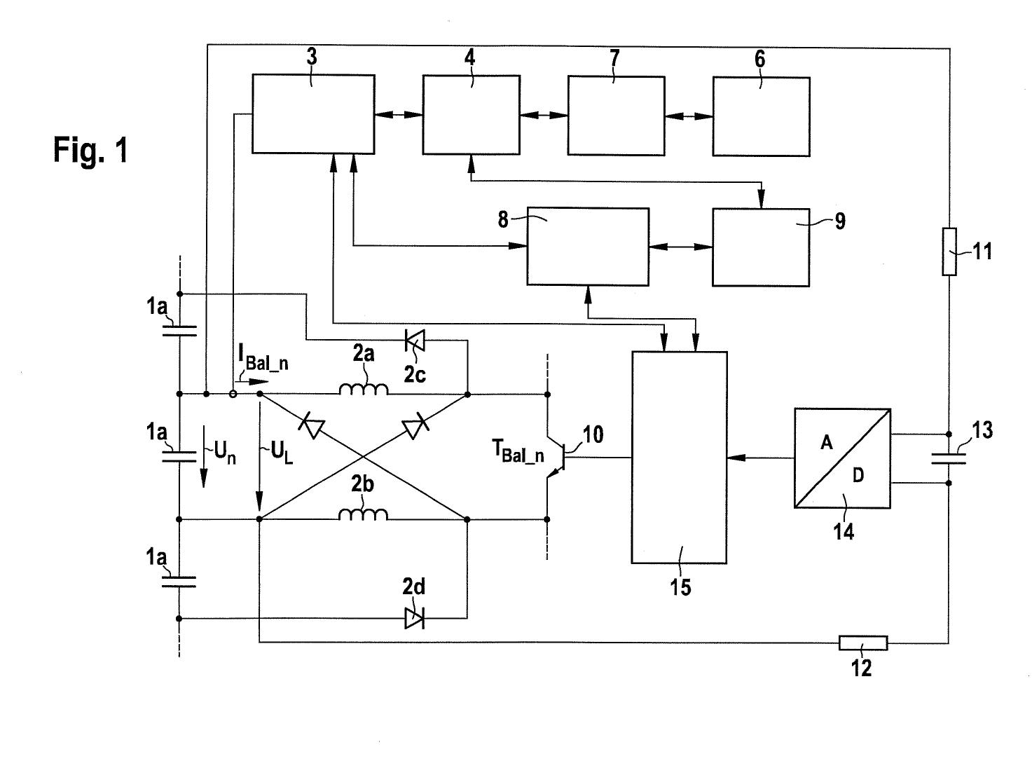

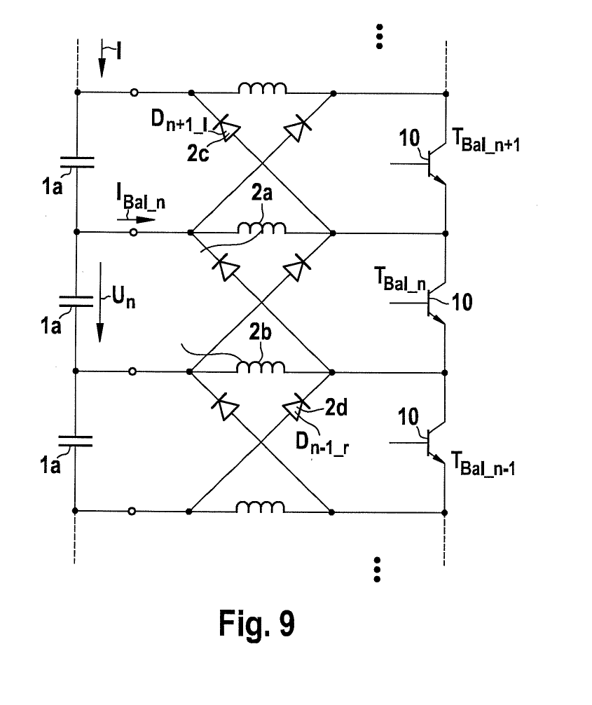

In FIG. 1, a preferred embodiment of the apparatus of the invention is shown; this is an expansion of the circuitry principle, shown in FIG. 9, for inductive cell balancing. In FIG. 1, a filter circuit 11, 12, 13 for preparing the differential voltage signal of the cell 1a (n) for an analog/digital converter 14 is also shown. By way of this converter, the cell voltage is furnished while adhering to the sampling theorem of a control and evaluation unit 15 of the cell 1a (n), which unit processes it and forwards it to the higher-order battery state detector 17b. The control and evaluation units 15 of all the cells 1a communicate with one another, in order to perform the cell balancing. Optionally along with the additional circuit elements shown, though they can preferably also be integrated with the control and evaluation unit 15, the circuit used for the cell balancing is also used for determining the internal resistance of the cell in accordance with the invention. In the invention, the circuit for the inductive cell balancing shown in FIG. 9 is expanded with a first control module 3, with which the voltage Uₙ applied to the battery cell 1a (n), or the voltage U_{L} applied to the chokes 2a, 2b, and the current (T_{Bal}_{_{—}}ₙ) flowing from the battery cell 1a (n) are detected at various times during the charge withdrawal. This can be done either via a direct current and voltage measurement or via the control and evaluation unit 15 of the cell 1a (n), which detects at least the battery voltage Uₙ, or the voltage U_{L} applied to the chokes 2a, 2b, via the filter comprising two resistors 11, 12 and a capacitor 13, and via an A/D converter 14, from which, as described below, the current (T_{Bal}_{_{—}}ₙ) flowing from the battery cell 1a (n) can be calculated. The first control module 3 is connected to an arithmetic unit 4, which as described below calculates the internal resistance of the battery cell as the quotient of the difference between two detected voltage values and the difference of two detected current values.

The charge that in the first step was drawn from the cell or cells 1a can be calculated as follows by way of the voltage/time area, for a known inductance of the reservoir 2 used for buffer-storage of the energy:
The course over time of the current in the inductive component 2 is

$${I}_{L} = \frac{1}{L} \int {U}_{L} d t \qquad ( 1 )$$

The maximum current at the end of the first step will be called I_{Lmax}.
The charge drawn in the first step can be calculated as follows:

Qₑₙₜ=∫I_{L}dt (2)

The voltage U_{L} at the inductive component can then—on the assumption of ideal electronic switches 10 with an on-state resistance toward 0 as well as an ideal inductive component 2 which has no internal ohmic resistance—be ascertained simply from the voltage or voltages Uₙ, of those cells from which the energy was drawn. Via equations (1) and (2), the discharging current as well as the charge drawn from the cells 1a can thus be determined. The non-ideal properties of the electronic switches 10 and of the inductive components 2, given suitable dimensioning of the components, result in only slight errors in ascertaining the charge that is drawn from the cell or cells 1a.

In an equivalent form, in the second step the re-storing of the buffer-stored energy into the cell or cells 1a can be calculated:
The course over time of the current in the inductive component 2 is

$${I}_{L} = {I}_{Lmax} + \frac{1}{L} \int {U}_{L} d t , in which {U}_{L} < 0 \qquad ( 3 a )$$

Once the current I_{L} has assumed the value 0, the following applies:

I_{L}=0 (3b)
The charge fed back in the second step can be calculated as follows:

Q_{zu}=I_{L}dt (4)

Thus the course of current during transporting of the charge and the drawn or fed-back charge can be determined during the cell balancing.

On the basis of this information, the internal resistance of the cells can be ascertained as follows:

Let the starting point for explaining the mode of operation be an operating state in which the battery is not outputting or drawing any power at its terminals. In this state, no current flows through the battery cells 1a. If the transistor 10 (T_{Bal}_{_{—}}ₙ) is then switched on, the cell 1a (n) discharges via the chokes 2a, 2b (Lₙ_{_{—}}ᵤₚₚₑᵣ and Lₙ_{_{—}}_{lower}). As a result of the switching on of the transistor 10 (T_{Bal}_{_{—}}ₙ), the cell voltage varies in comparison to the outset state (when no power is being output or drawn), and this voltage is detected by means of the aforementioned arrangement for cell voltage measurement. Naturally, the current that is flowing through the battery cell 1a (n) also varies in addition. This current can be determined in the manner described above.

The temperature-dependent, state-of-charge-dependent and aging-dependent internal resistance Rᵢ_{_{—}}ₙ of the battery cell 1a (n) can thus be determined for instance as follows:

$${R}_{i\_n} ( Temp , S O C , Aging ) = \frac{{U}_{n} \vert {T}_{Bal\_n ON} - {U}_{N} \vert {T}_{Bal\_n OFF}}{{I}_{Bal\_n} \vert {T}_{Bal\_n ON}} \qquad ( 5 )$$

For ascertaining the inner resistance, besides the output state (cell not loaded), an arbitrary time during the discharge phase of the cell 1a (n) can be used, for which the cell voltage and the cell current are ascertained in the manner described.

For a known dependency of the internal resistance on the cell temperature and on the state of charge of the cell, the aging-dependent increase in the internal resistance of the battery cell can be determined. For that purpose, the arithmetic unit 4 is connected to a first evaluation unit 7, which determines the aging-dependent increase in the internal resistance of the battery cell 1a (n) on the basis of the determined internal resistance and by consulting a table 6, which stores in memory the dependency of the internal resistance on the cell temperature, existing during the determination of the internal resistance, and on a state of charge of the battery cell 1a, existing during the determination of the internal resistance.

In a modification of the method, for determining the inner resistance of the cell 1a (n), it is also possible to use two or more times during the discharge phase of the cell 1a (n). Then the determination of the inner resistance is done via the differential voltage and the change in the balancing current, which occur between the observed times:

$${R}_{i\_n} ( Temp , S O C , Aging ) = \frac{Δ {U}_{n} \vert {T}_{Bal\_n ON}}{Δ {I}_{Bal\_n} \vert {T}_{Bal\_n ON}} \qquad ( 6 )$$

The method presented according to the invention for determining the inner resistance can for instance also be performed with the vehicle parked. As a result, the determination of the inner resistance is not adversely affected by the superimposed “normal operation” of the battery 1. This represents a substantial advantage over the methods known until now.

The procedure according to the invention described for ascertaining the inner resistance of the battery cells 1a (including in the modification described) can also be employed analogously during the phases in which the energy buffer-stored in the inductive components 2; 2a, 2b is fed back into the cells 1a. During these phases as well, the information about the actual values of the cell voltages Uₙ and the information about the courses over time of the balancing currents I_{L} are available to the system. Thus the method can be employed for ascertaining the internal resistance.

The principle presented according to the invention for determining the internal resistance of the battery cells can naturally be employed (including the phases of operation in which the battery is being charged) during the “normal operation” of the battery 1 as well. Then, to determine the internal resistance, the influence of the battery current flowing in the cell 1a, which at that time is superimposed on the balancing current, must be taken into account. However, this procedure is worthwhile only in operating states in which the battery 1 is being charged or discharged with low currents. For that purpose, the internal resistance Rᵢ_{_{—}}ₙ of the battery cell 1a (n) is determined again from the quotient of the differences in the cell voltage and in the cell current at two times.

In phases of operation in which the battery 1 is being charged or discharged with high currents, it makes little sense to bring about an additional “excitation” of the cell by loading via the balancing current. During such phases of operation, according to the invention the use of the method, employed in the prior art, is preferably employed for determining the internal resistance from the cell voltage and the cell current that result from the “normal operation” of the battery 1.

With the method presented for determining the internal resistance of the battery in accordance with the invention, one of the essential pieces of information that are required for battery state detection and prediction—the temperature-dependent, state of charge-dependent and aging-dependent change in the internal resistance of the battery cells—can be determined in all operating states of the battery. In the methods known until now, the internal resistance can be determined only in phases of operation in which the battery current changes significantly during the “normal operation”. In this way, it is possible to perform the determination of the internal resistance of the battery cells substantially more robustly and precisely than in the prior art.

According to the invention, the dependency on the frequency of the excitation is preferably determined. To that end, the following procedures are preferably employed:
variation of the frequency of the excitation at a constant pulse-duty factor
variation of the pulse-duty factor of the excitation at a constant frequency
combination of the first two.

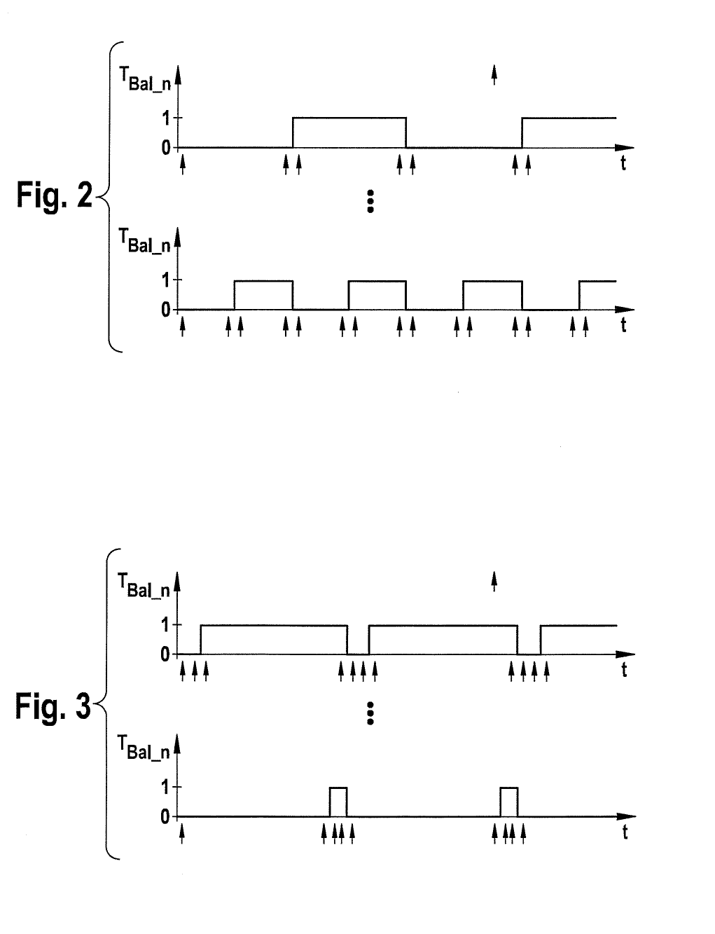

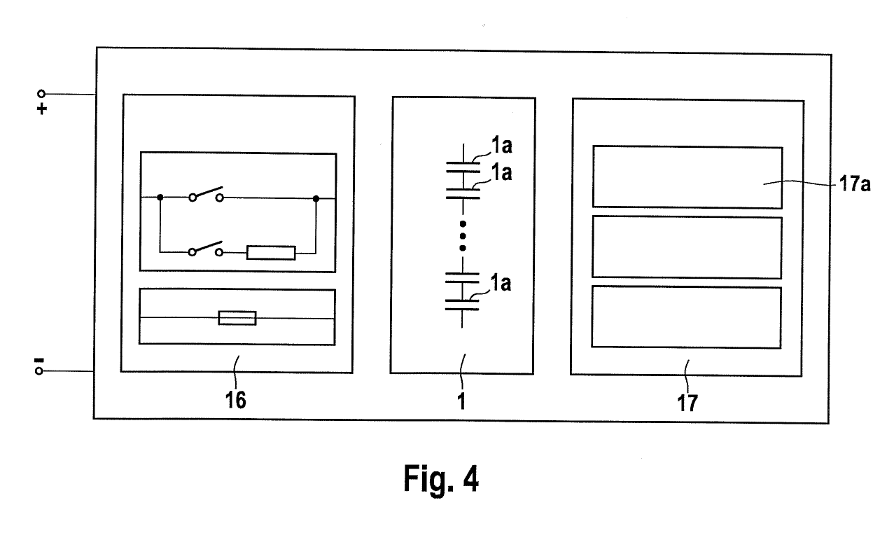

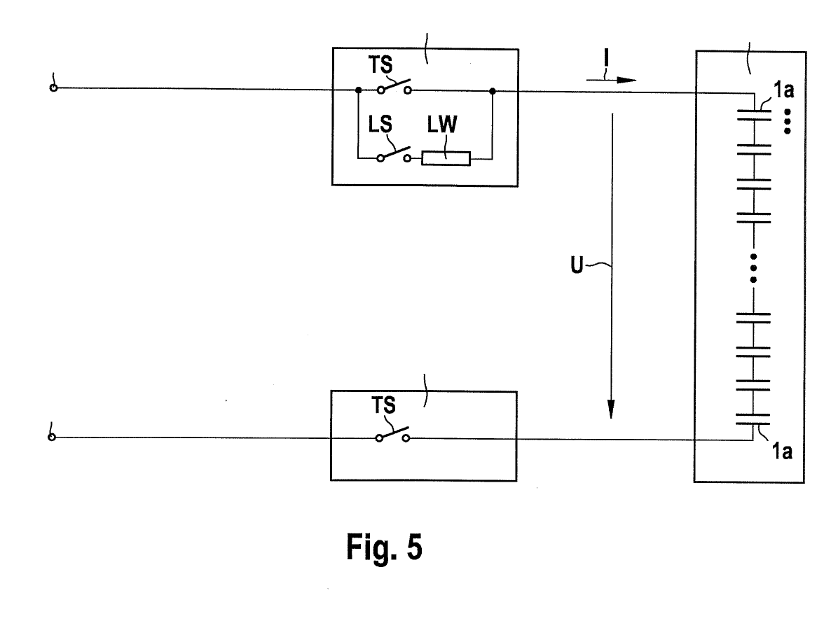

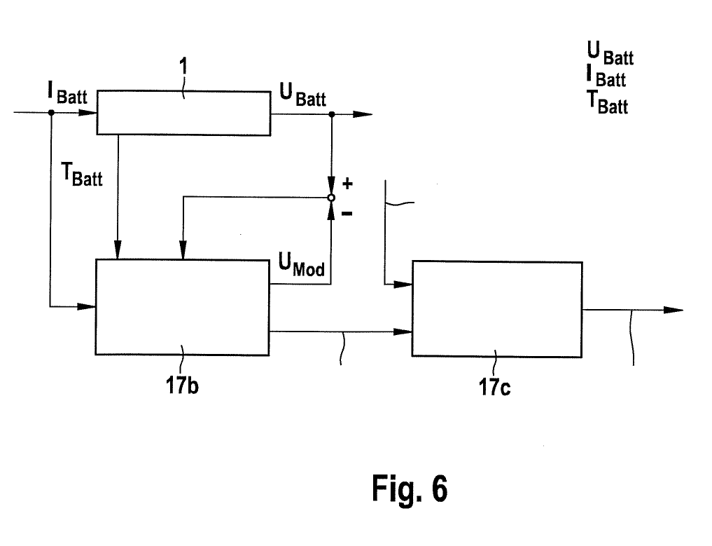

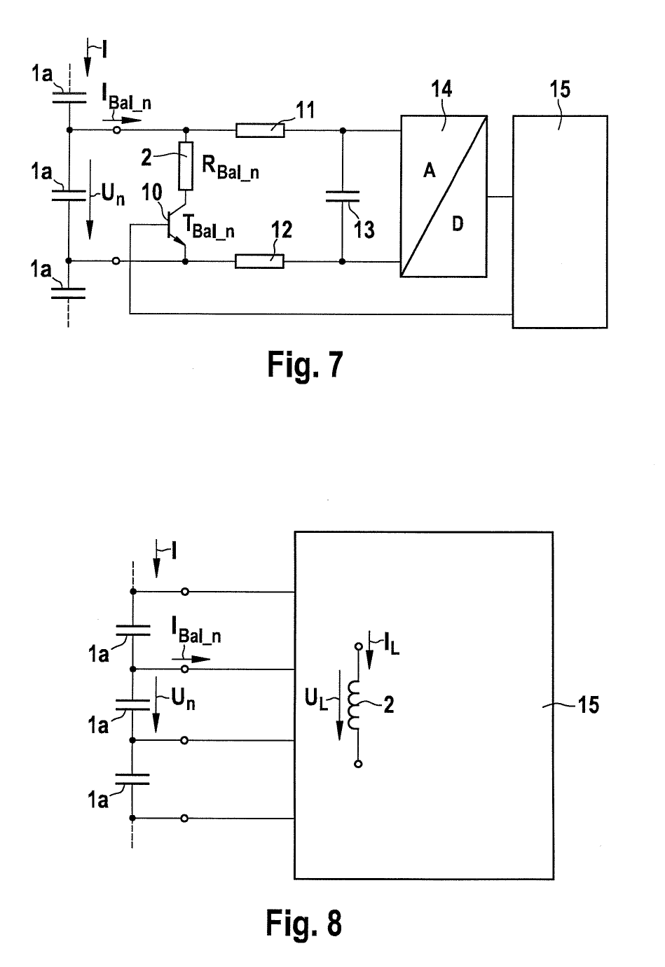

In FIG. 2, in the two courses over time for the triggering of the transistor 10 (T_{Bal}_{_{—}}ₙ), it is shown by way of example how the dependency of the impedance of the battery cells on the frequency of the excitation can be determined. The pulse-duty factor of the excitation is shown symmetrically in FIG. 2; that is, the ON time and the OFF time of the transistor are equal. In principle, the method can also be attained with asymmetrical pulse-duty factors; all that has to be taken into account is a maximum pulse-duty factor, which depends on the type and size of the energy reservoir 2 and cells 1a, since the buffer-stored energy has to be re-stored into the cells 1a. The frequency of the excitation is varied to determine the frequency dependency of the internal resistance. In FIG. 2, the courses are shown for two frequencies. In addition in FIG. 2, the measurement times are shown in the form of upward-pointing arrows, in which the internal resistance can be determined in accordance with equation (1). The measuring times are each selected here before and after a change in the switching state of the transistor 10 (T_{Bal}_{_{—}}ₙ).

In FIG. 3, a further possibility for determining the frequency dependency of the internal resistance of the battery cells is shown. Here, the pulse-duty factor of the excitation is varied, while the frequency is kept constant. In this method as well, the measuring times, shown as upward-pointing arrows, are each selected before and after a change in the switching state of the transistor 10 (T_{Bal}_{_{—}}ₙ). The frequency-dependent internal resistance of the battery cells is again determined in accordance with equation (5), or with suitable modification of the procedure, in accordance with equation (6).

In principle, combinations of the two methods described are naturally also possible for describing the internal resistance as a function of the excitation. The methods according to the invention make it possible, similarly to the procedure in what is known as impedance spectroscopy, to determine the frequency dependency of the internal resistance. In contrast to impedance spectroscopy, the methods according to the invention can be implemented without complicated additional measurement electronics. Only with regard to detecting the cell voltages are more-stringent demands in terms of dynamics and sampling frequency required, compared to the circuits conventionally used in battery systems.

To change the frequency and/or the pulse-duty factor of the excitation, a second control module 8, which is coupled to the first control module 3 and to the control and evaluation unit 15, is provided according to the invention. The second control module 8 is also connected to a second evaluation unit 9, which is likewise connected to the arithmetic unit 4. The second evaluation unit 9 determines the frequency dependency of the ohmic component of the internal resistance of the battery cell by evaluating the plurality of successive determinations of the internal resistance, taking into account the change in the frequency and/or the pulse-duty factor of the excitation.

With the preferred method presented for determining the frequency dependency of the internal resistance of the battery cells, it is equally possible for one piece of the essential information required for battery state detection and prediction—that is, the temperature-dependent, state-of-charge-dependent and aging-dependent change in the internal resistance of the battery cells—to be determined. In contrast to the methods known until now, the internal resistance can be determined only in phases of operation in which the battery current changes significantly during the “normal operation”. In this way it is possible to perform the successful determination of the internal resistance of the battery cells substantially more robustly and precisely, compared to the prior art.

In addition to the above written disclosure, the disclosure in the drawings is also expressly noted here.

1-10. (canceled)

11. A method for determining an internal resistance of a battery cell of a battery, in particular a traction battery, in which in the battery inductive cell balancing for compensating for states of charge of the battery cells is performed, in which a charge drawn from or supplied to a battery cell is determined via a determination of current flowing during drawing or supplying of a charge, the method having the steps of:
determining a first voltage applied to the battery cell and a first current, flowing from or to the battery cell, at a first time during withdrawal or delivery of a charge;
determining a second voltage applied to the battery cell and a second current, flowing from or to the battery cell, at a second time during the withdrawal or delivery of a charge; and
calculating the internal resistance of the battery cell as the quotient of a difference between the second voltage and the first voltage and a difference between the second current and the first current.

12. The method as defined by claim 11, wherein the first time is selected such that the first current is equal to zero, and the second time is an arbitrary time during an ensuing discharging phase or charging phase of the battery cell.

13. The method as defined by claim 11, wherein the first time is an arbitrary time during a discharging phase or charging phase of the battery cell, and the second time is an arbitrary time during a same discharging phase or charging phase of the battery cell.

14. The method as defined by claim 11, further comprising the step of determining an aging-dependent increase in the internal resistance of the battery cell based on a known dependency of the internal resistance on a cell temperature existing during determination of the internal resistance and a state of charge of the battery cell existing during the determination of the internal resistance.

15. The method as defined by claim 12, further comprising the step of determining an aging-dependent increase in the internal resistance of the battery cell based on a known dependency of the internal resistance on a cell temperature existing during determination of the internal resistance and a state of charge of the battery cell existing during the determination of the internal resistance.

16. The method as defined by claim 13, further comprising the step of determining an aging-dependent increase in the internal resistance of the battery cell based on a known dependency of the internal resistance on a cell temperature existing during determination of the internal resistance and a state of charge of the battery cell existing during the determination of the internal resistance.

17. The method as defined by claim 11, further comprising the step of determining a frequency dependency of the internal resistance of the battery cell by varying a frequency of an excitation of the inductive cell balancing during a plurality of successive determinations of the internal resistance and/or by a variation of a pulse-duty factor of an excitation of resistive cell balancing during a plurality of successive determinations of the internal resistance.

18. The method as defined by claim 12, further comprising the step of determining a frequency dependency of the internal resistance of the battery cell by varying a frequency of an excitation of the inductive cell balancing during a plurality of successive determinations of the internal resistance and/or by a variation of a pulse-duty factor of an excitation of resistive cell balancing during a plurality of successive determinations of the internal resistance.

19. The method as defined by claim 13, further comprising the step of determining a frequency dependency of the internal resistance of the battery cell by varying a frequency of an excitation of the inductive cell balancing during a plurality of successive determinations of the internal resistance and/or by a variation of a pulse-duty factor of an excitation of resistive cell balancing during a plurality of successive determinations of the internal resistance.

20. The method as defined by claim 14, further comprising the step of determining a frequency dependency of the internal resistance of the battery cell by varying a frequency of an excitation of the inductive cell balancing during a plurality of successive determinations of the internal resistance and/or by a variation of a pulse-duty factor of an excitation of resistive cell balancing during a plurality of successive determinations of the internal resistance.

21. An apparatus for determining the internal resistance of a battery cell of a battery, in particular a traction battery, in which in the battery inductive cell balancing for compensating for states of charge of the battery cells is performed, in which a charge drawn from or supplied to a battery cell is determined via a determination of current flowing during drawing or supplying of a charge, having:
a first control module which determines a first voltage applied to the battery cell and a first current flowing from or to the battery cell at a first time during withdrawal or delivery of charge and determines a second voltage applied to the battery cell and a second current flowing from or to the battery cell at a second time during the withdrawal or delivery of charge; and
an arithmetic unit which calculates the internal resistance of the battery cell as a quotient of a difference between the second voltage and the first voltage and a difference between the second current and the first current.

22. The apparatus as defined by claim 21, wherein the first control module selects the first time such that the first current is equal to zero, and determines the second time as an arbitrary time during an ensuing discharging phase or charging phase of the battery cell.

23. The apparatus as defined by claim 21, wherein the first control module determines the first time as an arbitrary time during a discharging phase or charging phase of the battery cell, and determines the second time as an arbitrary time during a same discharging phase or charging phase of the battery cell.

24. The apparatus as defined by claim 21, further comprising
a table, which stores in memory a dependency of the internal resistance on a cell temperature existing during determination of the internal resistance and on a state of charge of the battery cell existing during the determination of the internal resistance, and
a first evaluation unit, which determines an aging-dependent increase in the internal resistance of the battery cell based on the determined internal resistance and of consulting the table.

25. The apparatus as defined by claim 22, further comprising
a table, which stores in memory a dependency of the internal resistance on a cell temperature existing during determination of the internal resistance and on a state of charge of the battery cell existing during the determination of the internal resistance, and
a first evaluation unit, which determines an aging-dependent increase in the internal resistance of the battery cell based on the determined internal resistance and of consulting the table.

26. The apparatus as defined by claim 23, further comprising
a table, which stores in memory a dependency of the internal resistance on a cell temperature existing during determination of the internal resistance and on a state of charge of the battery cell existing during the determination of the internal resistance, and
a first evaluation unit, which determines an aging-dependent increase in the internal resistance of the battery cell based on the determined internal resistance and of consulting the table.

27. The apparatus as defined by claim 21, further comprising
a second control module for varying a frequency of an excitation of resistive cell balancing during a plurality of successive determinations of the internal resistance and/or for varying a pulse-duty factor of an excitation of the inductive cell balancing during a plurality of successive determinations of the internal resistance, and
a second evaluation unit for determining a frequency dependency of the internal resistance of the battery cell by evaluation of the plurality of successive determinations of the internal resistance.

28. The apparatus as defined by claim 22, further comprising
a second control module for varying a frequency of an excitation of resistive cell balancing during a plurality of successive determinations of the internal resistance and/or for varying a pulse-duty factor of an excitation of the inductive cell balancing during a plurality of successive determinations of the internal resistance, and
a second evaluation unit for determining a frequency dependency of the internal resistance of the battery cell by evaluation of the plurality of successive determinations of the internal resistance.

29. The apparatus as defined by claim 23, further comprising
a second control module for varying a frequency of an excitation of resistive cell balancing during a plurality of successive determinations of the internal resistance and/or for varying a pulse-duty factor of an excitation of the inductive cell balancing during a plurality of successive determinations of the internal resistance, and
a second evaluation unit for determining a frequency dependency of the internal resistance of the battery cell by evaluation of the plurality of successive determinations of the internal resistance.

30. The apparatus as defined by claim 24, further comprising
a second control module for varying a frequency of an excitation of resistive cell balancing during a plurality of successive determinations of the internal resistance and/or for varying a pulse-duty factor of an excitation of the inductive cell balancing during a plurality of successive determinations of the internal resistance, and
a second evaluation unit for determining a frequency dependency of the internal resistance of the battery cell by evaluation of the plurality of successive determinations of the internal resistance.
